(19) United States
(12) Patent Application Publication
(10) Pub. No.: US 2009/0101284 A1
(43) Pub. Date: Apr. 23, 2009

(54) Table for plasma processing apparatus and plasma processing apparatus

(75) Inventors: Masakazu Higuma, Nirasaki-Shi (JP); Shlnji Himori, Nirasaki-Shi (JP); Shoichiro Matsuyama, Nirasaki-Shi (JP); Atsushi Matsuura, Nirasaki-Shi (JP)

Correspondence Address: SMITH, GAMBRELL & RUSSELL, 1130 CONNECTICUT AVENUE, N.W., SUITE 1130, WASHINGTON, DC, 20036, US

(73) Assignee: Tokyo Electron Limited

(21) Appl. No.: 12/076,855

(22) Filed: Mar. 24, 2008

Related U.S. Application Data
(60) Provisional application No. 60/924,559, filed on May 21, 2007.

(30) Foreign Application Priority Data
Mar. 26, 2007 (JP) 2007-079717

(51) Int. Cl. C23C 16/00; H01L 21/306

(52) U.S. Cl. 156/345.51; 118/728; 118/723 R

(57) ABSTRACT

An object of the present invention is to suppress damage of an electrostatic chuck, by controlling stress exerted on each part of a table, which includes an electrically conductive material, i.e., an electrode for generating plasma, a dielectric layer for enhancing the in-plane uniformity of a plasma process, and an electrostatic chuck. The table for a plasma processing apparatus includes an electrically conductive member connected with a high frequency power source and adapted for plasma generation, for drawing ions present in the plasma, or for both thereof; a dielectric layer provided on a top face of the electrically conductive member, having a central portion and a peripheral portion that are different in thickness relative to each other, and adapted for providing uniformity of high frequency electric field intensity in a plane over the substrate to be processed; and an electrode film for an electrostatic chuck, provided in the dielectric layer and adapted for electrostatically chucking the substrate onto a top face of the dielectric layer. With such configuration, the stress exerted on the electrostatic chuck due to temperature change can be controlled.

### CROSS REFERENCE TO RELATED APPLICATIONS

This application is based upon the prior Japanese Patent Application No. 2007-079717 filed on Mar. 26, 2007, and a provisional application U.S. 60/924,559 filed on May 21, 2007, the entire contents of which are incorporated herein by reference.

### BACKGROUND OF THE INVENTION

1. Field of the Invention

The present invention relates to a table for placing thereon a substrate to be processed, such as a semiconductor wafer or the like, to which a plasma process is provided, and a plasma processing apparatus including the table.

2. Background Art

Among steps of manufacturing semiconductor devices, there are many steps, in which a processing gas is changed into plasma, as in the case of dry etching, chemical vapor deposition (CVD), ashing and the like, so as to provide a process to each substrate. As the plasma processing apparatus for performing such a process, for example, an apparatus of a type, which includes a pair of parallel and flat electrodes vertically arranged to be opposed to each other, such that high frequency electric power is applied between these electrodes to change the processing gas introduced therein into plasma, so as to provide the process to each substrate to be processed, such as the semiconductor wafer (hereinafter referred to as “the wafer”) or the like placed on the lower electrode, is frequently used.

In recent years, processes, to which “lower energy and higher density plasma,” i.e., plasma of lower ion energy and higher electron density, is required, have been increased. Therefore, in some cases, the frequency of the high frequency power for generating plasma is needed to be highly raised up to an extent of, for example, 100 MHz, as compared with conventional cases (of raising the frequency up to, for example, about ten-odd MHz). However, as the frequency of the power applied is increased, the field intensity tends to be elevated in a region corresponding to a central portion of the electrode surface, i.e., a central portion of the wafer, while the field intensity tends to be lowered at the periphery of the wafer. When the distribution of the field intensity is not uniform in such a manner, the electron density of the generated plasma will also be uneven. Thus, a necessary processing speed will vary with positions in the wafer, as such making it difficult to provide a result of the process excellent in the in-plane uniformity.

To address this problem, embedding a dielectric layer, such as a ceramic or the like, having a dielectric constant of about 3.5 to 8.5, in a central portion of the surface of the lower electrode has been studied, as disclosed in Patent Document 1. One example of embedding the dielectric layer will now be described with reference to FIG. 12. When high frequency power is applied to the lower electrode 101 of the plasma processing apparatus 100 from a high frequency power source 103, a high frequency electric current, which is propagated through the surface of the lower electrode 101 and reaches a top portion thereof due to a skin effect, will be made to flow toward the central portion along the surface of the wafer W while a part of the electric current is leaked toward the lower electrode 101 and then made to flow outward in the lower electrode 101. In a region in which the dielectric layer 104 for making the plasma uniform is provided, the high frequency electric current is made to flow deeper than the other regions, generating cavity cylindrical resonance of a TM mode, thus lowering the electric field around the central portion applied to the plasma from the surface of the wafer W. Consequently, the electric field in the wafer surface can be made uniform. Reference numeral 102 in the drawing designates the upper electrode, and PZ expresses the plasma. In this case, an electrostatic chuck adapted for electrostatically chucking the wafer W is provided at an uppermost layered portion of the table. As a chuck electrode used for the electrostatic chuck, a high resistance material, which can permit the high frequency electric current to be adequately transmitted therethrough, should be used, in order to prevent interference, caused by the material, with passage of the high frequency electric current through an electrode film as well as to avoid deterioration of an effect to be obtained by embedding the dielectric layer.

For instance, the lower electrode may be composed of a composite material of ceramic and a metal, such as a metal matrix composite (MMC), which has a low coefficient of linear expansion and a proper conductivity, and the surface of which is covered with an Insulating material, such as alumite or the like. However, for example, on and/or in the lower electrode, wiring and finely machined portions, such as holes or the like for communicating a fluid therethrough for temperature control of the wafer, are provided. In addition, alumite is not likely to be deposited or attached onto such a composite material. Therefore, it is quite difficult to cover such holes with alumite.

Accordingly, in the case of forming the lower electrode from the MMC, it is necessary to cover the MMC with the insulating material by using a separate approach, thus limiting a degree of freedom for design and raising the production cost. Furthermore, the MMC is not likely to be processed by laser welding, soldering and/or brazing. Therefore, it is quite difficult to perform reliable connection excellent in air tightness and/or water-tightness upon forming the holes for fluid passages as described above in the lower electrode. Moreover, the raw material itself for the MMC is considerably expensive.

Thus, a metal material is often selected as the lower electrode. In particular, aluminum is generally used. FIG. 13(a) shows one example of a wafer table having the lower electrode formed from aluminum. In the drawing, reference numeral 11 designates the lower electrode, and a dielectric 12, which is, for example, a sintered body, is embedded in the central portion as previously described. Side faces and a bottom face of the lower electrode 11 are covered and insulated with insulating members 13a, 13b, respectively. In the drawing, reference numeral 14 designates the electrostatic chuck adapted for electrostatically chucking and holding the wafer when applied with voltage. The electrostatic chuck 14 has a structure in which an electrode film 16 is embedded in an insulating material 15. The electrostatic chuck 14 is provided onto the lower electrode 11 through a spraying process for each part thereof.

However, aluminum has a relatively high coefficient of linear expansion, making difference in the coefficient of linear expansion greater, as compared with ceramic or the like used as the dielectric 12. Therefore, the lower electrode 11 and the dielectric 12 will be expanded and contracted with different ratios, respectively, due to temperature change, upon production and/or use of the table, as shown by arrows in FIG. 13(b). Consequently, greater stress tends to be focused on boundary portions between the lower electrode 11 and the dielectric 12. As a result, stress is also exerted on the electrostatic chuck 14 provided on the lower electrode 11 and dielectric 12, deforming the electrostatic chuck 14 as shown in FIG. 13(c), as such the electrostatic chuck may be so damaged that it can not properly hold the wafer.

Also in the case of forming the table by preparing the electrostatic chuck 14 from a sintered material and attaching it onto the lower electrode 11 via an adhesive 17, as shown in FIG. 14, rather than providing it onto the lower electrode 11 by the spraying process, the lower electrode 11 and the dielectric 12 are expanded and contracted in the same manner, due to temperature change, as in the case of the table shown in FIG. 13, as such the stress tends to be focused on the boundary portions between the lower electrode 11 and the dielectric 12. However, the stress exerted on the electrostatic chuck 14 can be controlled, to some extent, due to the adhesive 17, as compared with the table shown in FIG. 13. Nevertheless, the stress can not be sufficiently mitigated, thus bulging may tend to be caused on the surface of the electrostatic chuck 14 also in such a table.

Patent Document 1: TOKUKAI No. 2004-363552, KOHO (Paragraphs [0084] to [0085])

### SUMMARY OF THE INVENTION

The present invention was made in light of such circumstances, and it is therefore an object thereof to suppress damage of the electrostatic chuck, by controlling the stress exerted on each part of the table, which includes an electrically conductive member, i.e., the electrode for generating the plasma, the dielectric layer for enhancing the in-plane uniformity of the plasma process and the electrostatic chuck.

The present invention is a table for a plasma processing apparatus, used for supporting a substrate to be processed thereon, the table comprising: an electrically conductive member connected with a high frequency power source and adapted for plasma generation, for drawing ions present in the plasma, or for both of plasma generation and drawing ions; a dielectric layer provided on a top face of the electrically conductive member, having a central portion and a peripheral portion that are different in thickness relative to each other, and adapted for providing uniformity of high frequency electric field intensity in a plane over the substrate to be processed; and, an electrode film of an electrostatic chuck, provided in the dielectric layer and adapted for electrostatically chucking the substrate onto a top face of the dielectric layer.

The dielectric layer may include a projection, which projects downward such that its thickness of the central portion is greater than its thickness of the peripheral portion. Alternatively, the dielectric layer and the electrode film may be formed of sprayed materials, respectively. Alternatively, in this case, the dielectric layer is configured such that the whole body thereof is formed of the same sprayed material.

Another aspect of the present invention is a table for a plasma processing apparatus, used for supporting a substrate to be processed thereon, the table comprising: an electrically conductive member connected with a high frequency power source and adapted for plasma generation, for drawing ions present in the plasma, or for both of plasma generation and drawing ions; a first dielectric layer provided on a top face of the electrically conductive member, having a central portion and a peripheral portion that are different in thickness relative to each other, and adapted for providing uniformity of high frequency electric field intensity in a plane over the substrate to be processed; a second dielectric layer layered on the first dielectric layer in a range substantially the same as or smaller than a top face of the first dielectric layer; and an electrode film provided in the second dielectric layer or under the second dielectric layer and adapted for electrostatically chucking the substrate onto the second dielectric layer.

In this table, for example, the first dielectric layer includes a projection, which projects downward such that its thickness of the central portion is greater than its thickness of the peripheral portion. Alternatively, for example, the first dielectric layer is formed of a sintered material. The second dielectric layer and the electrode film may be formed of sprayed materials, respectively.

Still another aspect of the present invention is a table for a plasma processing apparatus, used for supporting a substrate to be processed thereon, the table comprising: an electrically conductive member connected with a high frequency power source and adapted for plasma generation, for drawing ions present in the plasma, or for both of plasma generation and drawing ions; a first dielectric layer provided to cover the whole top face of the electrically conductive member, and having a central portion and a peripheral portion that are formed from materials different from each other, such that the dielectric constant of the peripheral portion is higher than the dielectric constant of the central portion in order to provide uniformity of high frequency electric field intensity in a plane over the substrate to be processed; a second dielectric layer layered on the first dielectric layer; and an electrode film provided in the second dielectric layer or under the second dielectric layer and adapted for electrostatically chucking the substrate onto the second dielectric layer.

The first dielectric layer may be formed of a sprayed material or of a sintered material. Alternatively, the first dielectric layer may have top and bottom faces including a flat shape.

The electrode film is composed of a high resistance material, and in this case, volume resistivity of the electrode film is, for example, within a range of from 10⁻¹Ω·cm to 10⁸Ω·cm.

The present invention is a plasma processing apparatus comprising: a processing vessel adapted to provide a plasma process to a substrate to be processed; a processing gas introducing unit for introducing a processing gas into the processing vessel; a table for the plasma processing apparatus, provided in the processing vessel; an upper electrode provided above the table such that it faces the table; and a means configured to evacuate the interior of the processing vessel, wherein the table includes: an electrically conductive member connected with a high frequency power source and adapted for plasma generation, for drawing ions present in the plasma, or for both of plasma generation and drawing ions; a dielectric layer provided on a top face of the electrically conductive member, having a central portion and a peripheral portion that are different in thickness relative to each other, and adapted for providing uniformity of high frequency electric field intensity in a plane over the substrate to be processed; and an electrode film for an electrostatic chuck, provided in the dielectric layer and adapted for electrostatically chucking the substrate onto a top face of the dielectric layer.

The present invention is a plasma processing apparatus comprising: a processing vessel adapted to provide a plasma process to a substrate to be processed; a processing gas introducing unit for introducing a processing gas into the processing vessel; a table for the plasma processing apparatus, provided in the processing vessel; an upper electrode provided above the table such that it faces the table; and a means configured to evacuate the interior of the processing vessel, wherein the table includes: an electrically conductive member connected with a high frequency power source and adapted for plasma generation, for drawing ions present in the plasma, or for both of plasma generation and drawing ions; a first dielectric layer provided on a top face of the electrically conductive member, having a central portion and a peripheral portion that are different in thickness relative to each other, and adapted for providing uniformity of high frequency electric field intensity in a plane over the substrate to be processed; a second dielectric layer layered on the first dielectric layer in a range substantially the same as or smaller than a top face of the first dielectric layer; and an electrode film provided in the second dielectric layer or under the second dielectric layer and adapted for electrostatically chucking the substrate onto the second dielectric layer.

The present invention is a plasma processing apparatus comprising: a processing vessel adapted to provide a plasma process to a substrate to be processed; a processing gas Introducing unit for introducing a processing gas into the processing vessel; a table for the plasma processing apparatus, provided in the processing vessel; an upper electrode provided above the table such that it faces the table; and a means configured to evacuate the interior of the processing vessel, wherein the table includes: an electrically conductive member connected with a high frequency power source and adapted for plasma generation, for drawing ions present in the plasma, or for both of plasma generation and drawing ions; a first dielectric layer provided to cover the whole top face of the electrically conductive member, and having a central portion and a peripheral portion that are formed from materials different from each other, such that the dielectric constant of the peripheral portion is higher than the dielectric constant of the central portion in order to provide uniformity of the high frequency electric field intensity in a plane over the substrate to be processed; a second dielectric layer layered on the first dielectric layer; and an electrode film provided in the second dielectric layer or under the second dielectric layer and adapted for electrostatically chucking the substrate onto the second dielectric layer.

According to the present invention, the dielectric layer, which has the central portion and the peripheral portion different in thickness relative to each other in order to provide uniformity of the electron density distribution of the plasma, covers the whole top face of the electrically conductive member, and the electrode film is provided in the dielectric layer. With such configuration, the electrostatic chuck as described above in the column on the background art can be constituted from an upper portion of the dielectric layer and the electrode film. However, in this configuration, it should be noted that there is no boundary portion between the dielectric layer and the lower electrode, i.e., the electrically conductive member, on the bottom face side of the electrostatic chuck. Consequently, even when the temperature of the table is changed during production and/or use thereof, the stress exerted on the electrostatic chuck can be securely suppressed, thereby avoiding or suppressing the damage of the electrostatic chuck.

According to another aspect of this invention, the electrostatic chuck is formed by providing the first dielectric layer on the top face of the electrically conductive member, the first dielectric layer being formed such that its thickness of the central portion is greater than its thickness of the peripheral portion in order to provide uniformity of the electron density distribution of the plasma, as well as by laminating the second dielectric layer on the first dielectric layer within the range substantially the same as or smaller than the top face of the first dielectric layer. Therefore, again, there is no boundary portion between the first dielectric layer and the electrically conductive member on the bottom face side of the electrostatic chuck. Instead, the boundary portion, when viewed from the electrostatic chuck, exists in an outer circumference of the electrostatic chuck. As such, even when the temperature of the table is changed during production and/or use thereof, the stress exerted on the electrostatic chuck can be suppressed, thereby avoiding or suppressing the damage of the electrostatic chuck.

According to still another aspect of this Invention, a first dielectric layer having a central portion and a peripheral portion that are formed from materials different from each other, such that the dielectric constant of the peripheral portion is higher than the dielectric constant of the central portion, is provided, as a dielectric layer adapted for providing uniformity of the electron density distribution of the plasma. Accordingly, the difference in the coefficient of linear expansion of the materials different from each other can be significantly lessened, as compared with the difference in the coefficient of linear expansion between the electrically conductive member and the dielectric layer respectively provided below the electrostatic chuck of the conventional table. Therefore, stress exerted on the second dielectric layer constituting the electrostatic chuck, due to temperature change, can be suppressed. Thus, even when the temperature of the table is changed during production and/or use thereof, the stress exerted on the electrostatic chuck can be suppressed, thereby avoiding or suppressing the damage of the electrostatic chuck.

### BRIEF DESCRIPTION OF THE DRAWINGS

FIG. 1 is a longitudinal sectional view of a plasma processing apparatus including a table related to one embodiment of the present invention.

FIG. 2 is a longitudinal sectional view of the table.

FIG. 3 (a) (b) (c) (d) are views Illustrating a production process for the table.

FIG. 4 (a) (b) (c) (d) are longitudinal sectional views showing a variation of the table.

FIG. 5 is a longitudinal sectional view of the table related to another embodiment.

FIG. 6 (a) (b) (c) (d) (e) are views illustrating the production process for the table of FIG. 5.

FIG. 7(a) (b) (c) are longitudinal sectional views showing a variation of the table.

FIG. 8 is a longitudinal sectional view showing another variation of the table.

FIG. 9 (a) (b) (c) (d) are views illustrating the production process for the variation of FIG. 8.

FIG. 10 (a) (b) are longitudinal sectional views of the table related to still another embodiment.

FIG. 11(a) (b) are longitudinal sectional views showing a variation of the table.

FIG. 12 is a view for explaining a prior art example of the plasma processing apparatus including the table.

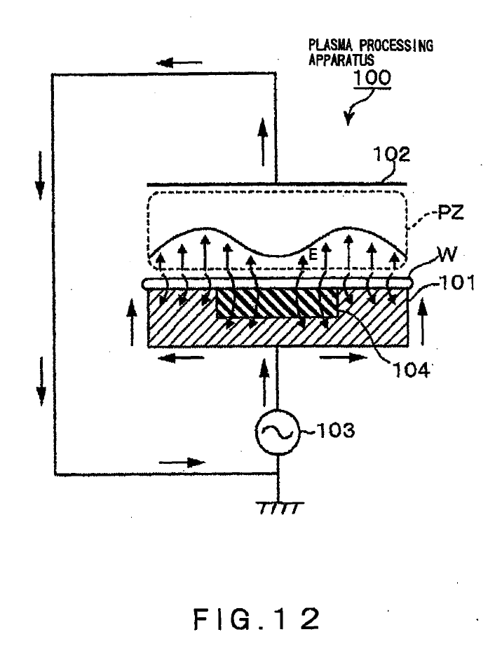

FIG. 13 (a) (b) (c) are views showing a manner in which an electrostatic chuck is deformed in the conventional table.

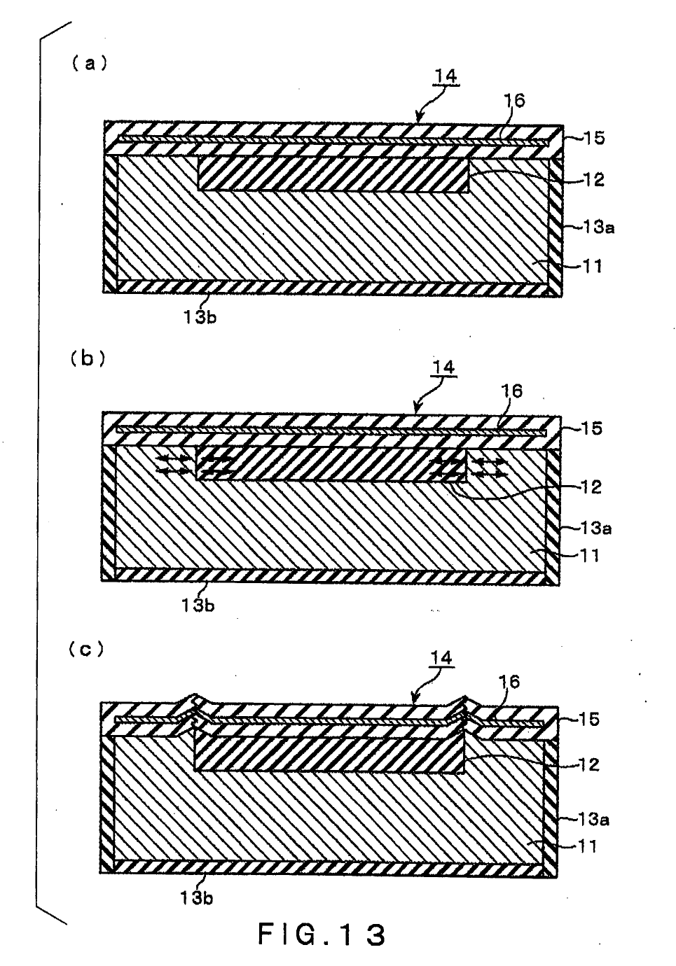

FIG. 14 is a view showing another construction of the conventional table.

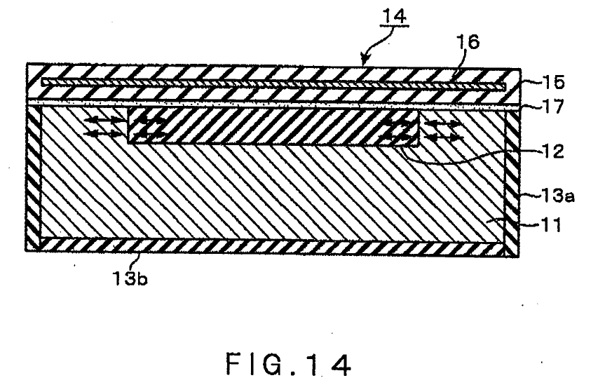

### DETAILED DESCRIPTION OF THE INVENTION

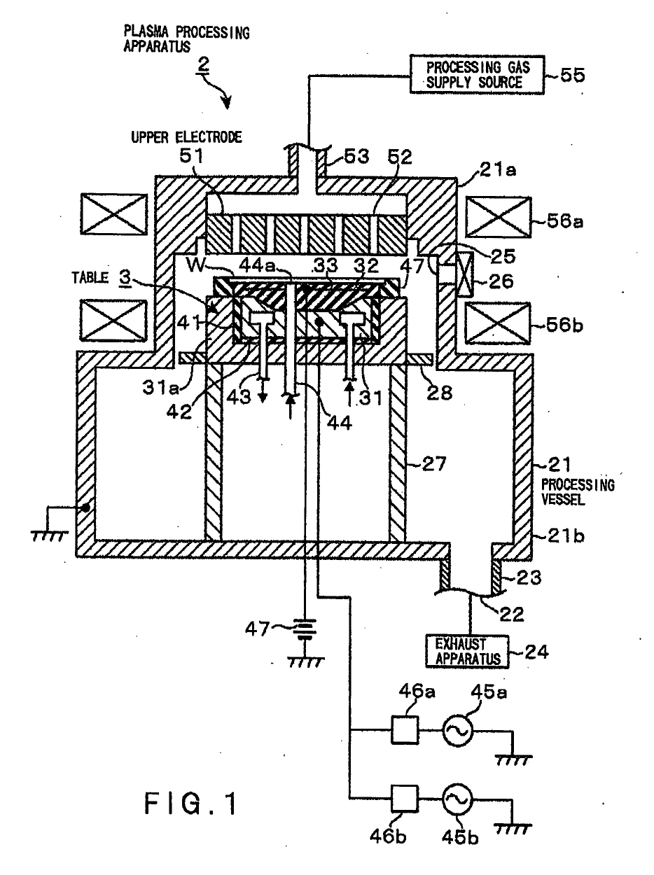

The table related to a first embodiment of the present invention will be described, with reference to FIG. 1, with respect to one example applied to the plasma processing apparatus used as an etching apparatus. FIG. 1 shows one example of a reactive ion etching (RIE) plasma processing apparatus. The plasma processing apparatus 2 includes a processing vessel 21 composed of, for example, a vacuum chamber, the interior of which defines a hermetically sealed space, a table 3 located at a central portion of a bottom face in the processing vessel 21, and an upper electrode 51 provided above the table 3 such that it faces the table 3.

The processing vessel 21 includes a cylindrical upper chamber 21a having a smaller diameter and a cylindrical lower chamber 21b having a greater diameter. The upper chamber 21a and the lower chamber 21b are in communication relative to each other, and the whole body of the processing chamber 21 is formed into an airtight structure. The table 3 and the upper electrode 51 are stored in the upper chamber 21a, while a support plate 27, which is adapted to support the table 3 and in which pipelines are contained, is stored in the lower chamber 21b. An exhaust apparatus 24 is connected with an exhaust port 22 of the bottom face of the lower chamber 21b via an exhaust pipe 23. To the exhaust apparatus 24, a pressure control unit (not shown) is connected. The pressure control unit is configured to evacuate the whole interior of the processing vessel 21 so as to keep it at a desired degree of vacuum, in accordance with a signal sent from a control unit (now shown). In a side face of the upper chamber 21a, a transfer port 25 for a wafer W that is a substrate to be processed is provided. The transfer port 25 can be opened and closed by a gate valve 26. The processing vessel 21 is composed of an electrically conductive member formed from aluminum or the like, and is grounded.

The table 3 has a structure, in which a lower electrode 31, an electrically conductive member formed of, for example, aluminum, for generating plasma, and a dielectric layer 32 provided to cover a central portion of a top face of the lower electrode 31 and adapted for controlling the electric field to be uniform, are layered, in this order, when viewed from below. In the dielectric layer 32, an electrode film 33 is embedded. The table 3 also includes Insulating members 41, 42, the insulating member 41 covering a side circumferential face of the lower electrode 31 while the insulating member 42 covering a bottom face of the lower electrode 31. The lower electrode 31 is fixed to a support table 31a located on the support plate 27 via these insulating members 41, 42, thus being in an electrically well insulated state relative to the processing vessel 21. The construction of the table 3 will be further detailed below.

In the lower electrode 31, a coolant passage 43 is formed for flowing a coolant therethrough. When the coolant is flowed through the coolant passage 43, the lower electrode 31 is cooled, so that the wafer W placed on a mounting face, a top face of the dielectric layer 32, can be cooled to a desired temperature.

A through-hole 44a for injecting a heat conductive back-side gas is provided in the dielectric layer 32, wherein the back-side gas is used for enhancing heat conductivity between the mounting face and a rear face of the wafer W. The through-hole 44a is in communication with a gas passage 44 formed in the lower electrode 31 and the like, so that the back-side gas, such as helium (He) or the like, supplied from a gas supply source (not shown) can be injected via the gas passage 44.

To the lower electrode 31, a first high frequency power source 45a for supplying high frequency electric power having a frequency of, for example, 100 MHz, and a second high frequency power source 45b for supplying high frequency electric power having a frequency of, for example, 3.2 MHz that is lower than the frequency of the first high frequency power source 45a are connected via matching devices 46a, 46b, respectively. The high frequency electric power supplied from the first high frequency power source 45a serves to change a processing gas as described later into plasma, and the high frequency electric power supplied from the second high frequency power source 45b serves to draw ions present in the plasma into the surface of the wafer W by applying bias electric power to the wafer W.

On the outer periphery of the top face of the lower electrode 31, a focus ring 47 is provided to surround the dielectric layer 32. The focus ring 47 serves to control a state of plasma in an outward region of the periphery of the wafer W. For Instance, it serves to spread the plasma wider than the wafer W so as to enhance uniformity of an etching rate in the wafer surface.

On the outside of a bottom portion of the support table 31a, a baffle plate 28 is provided to surround the support table 31a. The baffle plate 28 serves as a gas distributor for controlling a flow of the processing gas, by causing the processing gas present in the upper chamber 21a to flow through a gap formed between the baffle plate 28 and a side wall of the upper chamber 21a into the lower chamber 21b.

The upper electrode 51 is formed in a hollow state and has a large number of gas supply holes 52 formed in its bottom face and arranged in, for example, a uniformly dispersed state, such that they can constitute a gas shower head. Thus, the gas supply holes 52 serve to supply and disperse the processing gas into the processing vessel 21. A gas introducing pipe 53 is provided above a central portion of a top face of the upper electrode 51. The gas introducing pipe 53 extends through a central portion of a top face of the processing vessel 21, and is connected with a processing gas supply source 55 on the upstream side. The processing gas supply source 55 includes a control mechanism (not shown) for controlling a supply amount of the processing gas, and is adapted to start or stop the supply of the processing gas as well as to increase or decrease the supply amount of the processing gas for the plasma processing apparatus 2. Due to fixation of the upper electrode 51 to a side wall of the upper chamber 21a, an electrically conductive path is created between the upper electrode 51 and the processing vessel 21.

Furthermore, two multi-boring-type magnets 56a, 56b are respectively arranged above and below the transfer port 25 around the upper chamber 21a. Each multi-boring-type magnet 56a, 56b is configured such that a plurality of anisotropic and columnar segment magnets are attached to a ring-like ferromagnetic casing, wherein each adjacent pair of columnar segment magnets are arranged to be reversely oriented relative to each another. Consequently, a line of magnetic force is created between each adjacent pair of columnar segment magnets, thus forming a magnetic field around a processing space defined between the upper electrode 51 and the lower electrode 31, thereby confining the plasma Into the processing space. It is also contemplated that this apparatus may be configured not to include the multi-boring-type magnets 56a, 56b.

With the configuration described above, a pair of parallel flat-plate electrodes composed of the lower electrode 31 and the upper electrode 51 are provided in the processing vessel 21 (or upper chamber 21a) of the plasma processing apparatus 2. After the interior of the processing vessel 21 is adjusted to a vacuum, the processing gas is changed into plasma, by supplying the processing gas into the vessel 21 and applying high frequency electric power thereto from the high frequency power sources 45a, 45b, respectively. In this case, the high frequency electric current is flowed along a route from the lower electrode 31, through the plasma and upper electrode 51, along the wall of the processing vessel 21, up to an earth. With such an effect of the plasma processing apparatus 2, etching due to the plasma is provided to the wafer W fixed onto the table 3.

### EXAMPLES

### First Embodiment

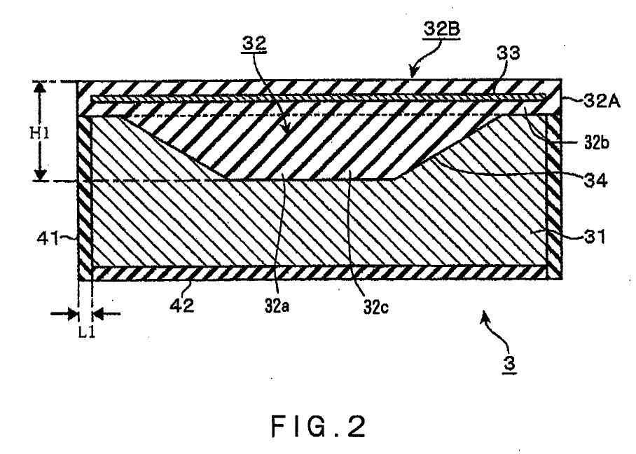

Next, the table 3 will be described in more detail with reference to FIG. 2. In a longitudinal side sectional view of the table 3 shown in FIG. 2, the coolant passage 42, back-side gas through-holes 43 and the like are omitted for convenience.

The lower electrode 31 has, for example, a circular shape, and its circumferential face is covered with the insulating member 41, as described above. The insulating member 41 is formed from, for example, alumite, or from ceramic formed by spraying. A thickness of the insulating member 41, as shown by L1 in the drawing, is, for example, 50 μm, in the case in which the insulating member 41 is formed of alumite, while, for example, several hundred microns, in the case in which it is formed of ceramic. The insulating member 42 covering the bottom face of the lower electrode 31 is composed of, for example, alumite.

In the top face of the lower electrode 31, an inverted frustum-shaped or cone-shaped recess 34 of a size smaller than the lower electrode 31 is formed. Namely, the depth of the recess 34 becomes gradually greater as one moves from a position slightly inner than the periphery of the lower electrode 31 toward its central portion. The dielectric layer 32 provided on the lower electrode 31 is configured to cover the whole top face of the insulating member 41 and lower electrode 31, and includes a projection 32c formed to project downward such that the thickness of its central portion 32a is greater than the thickness of its peripheral portion 32b. The projection 32c is filled in the recess 34. The top face of the dielectric layer 32 has a flat face so that the wafer W can be placed thereon. The dielectric layer 32 is formed of a material, for example, ceramic, such as alumina (Al₂O₃) or aluminum nitride (AlN), and is configured to have a dielectric constant (ε) within a range of from 8 to 9. The shape of the dielectric layer 32 having the depth that becomes gradually greater as one moves toward the central portion serves to weaken the electric field intensity of the central portion of the lower electrode 31 as compared with the peripheral portion of the lower electrode 31, thereby to provide uniformity of electron distribution density of the plasma over the wafer W.

The electrode film 33 is embedded in a top portion of the dielectric layer 32. The electrode film 33 is formed of a high resistance material in order to prevent interference with passage of the high frequency electric current through the electrode film 33 as well as to avoid suppression or deterioration of an effect to be obtained by providing the dielectric layer 32. The high resistance material means a material that satisfies the following expression:

δ/t≧1.000,

wherein δ=(2/ωμσ)^{1/2}, ω=2 nf, and σ=1/ρ. Furthermore, in the above expression, t=a thickness of the electrode film for an electrostatic chuck; δ=a skin depth of the electrode film for the electrostatic chuck relative to the high frequency electric power supplied from the high frequency power source; f=a frequency of the high frequency electric power supplied from the high frequency power source; n=the ratio of the circumference of a circle to its diameter; μ=magnetic permeability of the electrode for the electrostatic chuck; and ρ=resistivity of the electrode for the electrostatic chuck.

More specifically, the high resistance material is composed of, for example, an electrode material, such as Si, Cr₂O₃ or the like, and/or an electrode material of alumina (Al₂O₃) containing Cr₂O₃ and/or alumina containing molybdenum carbide (MoC), or the like. The high resistance material is more resistive than common electrode materials, but has a value of resistance lower than that of the dielectric layer 32 because of a need to function as the electrode. The volume resistivity of the dielectric layer is within a range of from 10⁹Ω·cm to 10¹⁶Ω·cm. Accordingly, assuming that the frequency of the high frequency electric power is 100 MHz and that the thickness of the electrode layer is several microns to several ten microns in the above expression, it is preferred that the volume resistivity of the electrode film is greater than 10⁻¹Ω·cm but lower than 10⁸Ω·cm. Namely, the material lower than 10⁻¹Ω·cm can not exhibit the effect of the dielectric layer 32, while the material higher than 10⁸Ω·cm can not be adapted for a chucking function that is basically required for the electrostatic chuck.

As shown in FIG. 1, the electrode film 33 is connected with a high voltage direct current power source 47. When high voltage direct current electric power is applied from the high voltage direct current power source 47 to the electrode film 33, the wafer W will be electrostatically chucked onto the dielectric layer 32 due to the Coulomb force generated over the surface of the dielectric layer 32. Namely, in the table 3, a portion of the insulating material surrounding the electrode for the electrostatic chuck for chucking and holding the wafer W as described in the background art, as well as the dielectric layer used for weakening the field intensity of the central portion of the lower electrode 31 relative to the field intensity of its peripheral portion in order to provide uniformity of the electron distribution density of the plasma are integrally formed from the same material. Hereinafter, for convenience, the portion surrounding the electrode film 33 (or upper portion relative to a dot line in FIG. 2) of the dielectric layer 32 will be referred to as an insulating material portion 32A. In addition, a combined body composed of the Insulating material portion 32A and electrode film 33 will be referred to as an electrostatic chuck 32B.

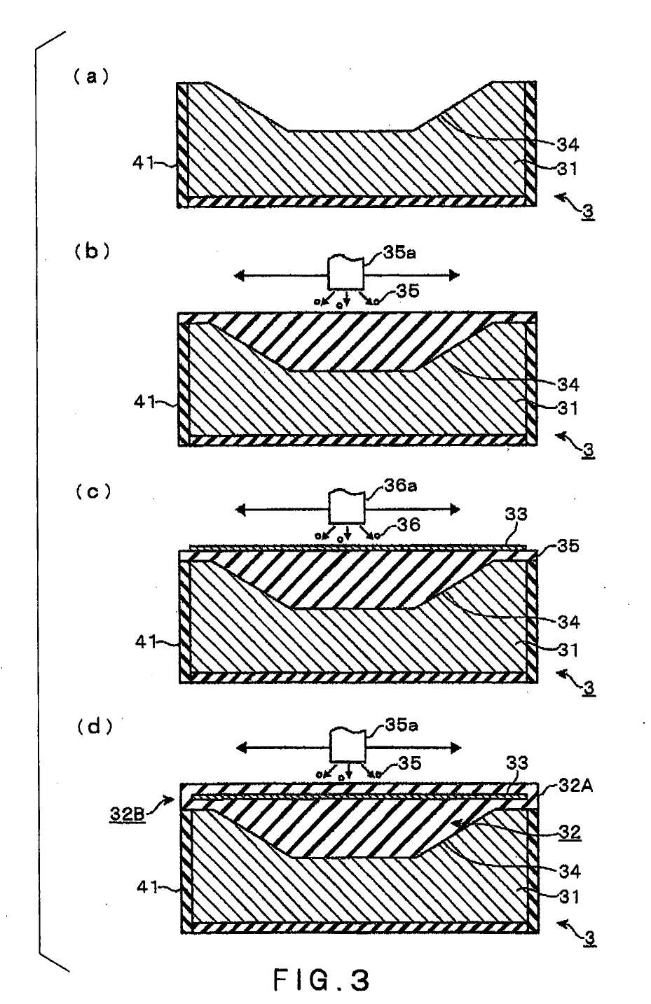

Now, referring to FIG. 3, one example of a production process for the table will be described. First, a dielectric layer forming material 35 is sprayed from a nozzle 35a into the recess 34 so as to fill the recess 34 with the material 35. Thus, a part of the dielectric layer 32 except for the electrostatic chuck 32B is formed while a top face of the lower electrode 31 is covered with the material 35 (FIGS. 3(a), 3(b)). Thereafter, for example, an electrode film forming material 36 is sprayed from a nozzle 36a so as to form the electrode film 33 (FIG. 3(c)), and the material 35 is again sprayed from the nozzle 35a so as to cover the electrode film 33 therewith, thereby to form the entire body of the dielectric layer 32 and create the electrostatic chuck 32B. In this way, the table 3 is produced (FIG. 3(d)). While the dielectric layer 32 may be provided as a sintered body, it is preferred that the layer 32 is constructed by utilizing the spraying process. This is because such a spraying process can facilitate to form the dielectric layer 32 such that the thickness becomes gradually greater as one moves toward its central portion in order to provide uniformity of the plasma electron distribution density as described above. In addition, with respect to the electrode film of the current invention, it is necessary to form it with the volume resistivity of the material controlled within a certain range. If utilizing the spraying process, however, optional control of the volume resistivity can be facilitated by addition of an electrically conductive material, such as Cr₂O₂ or the like, to a base material, such as Al₂O₃ or the like. This is significantly advantageous.

In the case of forming the dielectric layer 32 by utilizing the spraying process as described above, It is preferred that the thickness of the dielectric layer 32, as is shown by H1 in FIG. 2, is, for example, 2 mm or less, in order to suppress or avoid damage caused by internal stress of the sprayed material itself.

According to this embodiment, the insulating material portion 32A surrounding the electrode film 33 of the electrostatic chuck 32B for chucking and holding the wafer W in the conventional table as described above in the column on the background art as well as the dielectric used for controlling the field intensity of the central portion of the lower electrode 31 are formed from the same material into the so-called integrated body. Therefore, the electrostatic chuck can be regarded as a single body composed of the dielectric layer 32 and electrode film 33. In the conventional table, as described in the column on the background art, the dielectric layer and the lower electrode are provided under the electrostatic chuck, while respectively having different coefficients of linear expansion. On the other hand, in the table 3 of this embodiment, when assuming that the dielectric layer 32 and the electrode film 33 constitute together a single electrostatic chuck, the lower electrode 31 is provided to extend under the electrostatic chuck. Therefore, there is no boundary portion, on which the stress caused by the difference of mutual coefficients of linear expansion would be focused as in the case of the conventional table, between the dielectric layer and the lower electrode. As a result, even when the temperature of the table 3 is changed during production and/or use thereof, the stress (i.e., thermal stress) exerted on the electrostatic chuck 32B can be suppressed, thereby avoiding or suppressing damage of the electrostatic chuck. With such construction, aluminum can be used as the lower electrode, and the dielectric layer and electrode film can be formed by the spraying process. Therefore, lower-cost production can be achieved.

As in the case of the conventional table, in which the dielectric (corresponding to the Insulating material portion 32A) of the electrostatic chuck and the dielectric used for providing uniformity of the plasma electron density are respectively formed from different materials, the coefficients of linear expansion are different in the respective materials. Therefore, the stress should be exerted between the electrostatic chuck and the dielectric due to temperature change. On the other hand, in this embodiment, the insulating material portion 32A and the lower dielectric layer 32 are formed from the same material by the spraying process. Therefore, the stress mutually exerted between the Insulating material portion 32A and the lower dielectric layer 32 due to temperature change can be significantly suppressed. Accordingly, damage of the electrostatic chuck 32B caused by such stress can be securely avoided.

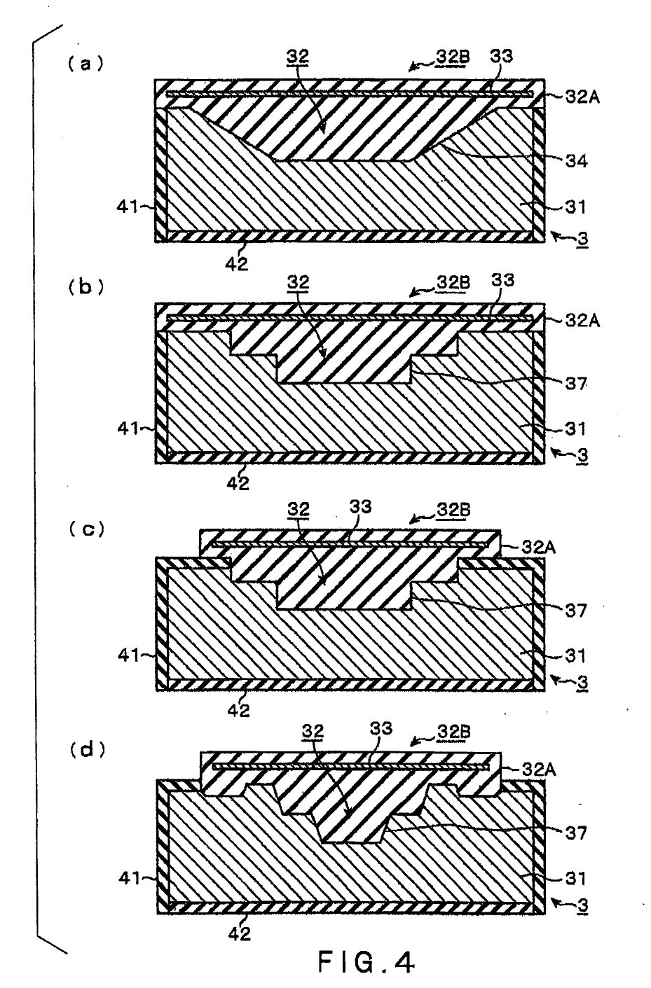

In the case of forming the table 3 in the procedure described above, the lower electrode 31 may be formed to have rounded corners, as shown in FIG. 4(a), at connecting portions between the side faces of the recess 34, bottom face of the recess 34 and top face of the electrode 31. In such a case, when the dielectric layer 32 is formed by the spraying process as described above, respectively corresponding corners of the dielectric layer 32 filled in the recess 34 can also be rounded. Therefore, the stress that the corners of the dielectric layer 32 will receive from the lower electrode 32 can be suppressed more positively.

A table 3A shown in FIG. 4(b) is a variation of the table 3 and differs from the table 3 in that the lower electrode 31 is provided with a circular step-wise recess 37 in place of the recess 34 described above. The step-wise recess 37 includes recessed portions whose depth is gradually deeper as one moves toward its central portion. On the other hand, lower portions of the dielectric layer 32 are formed to project corresponding to the shape of the recess 37 so as to be filled in the recess 37. The construction of such a table can also provide the same effect as the table 3 described above. While the Insulating material portion 32A and the lower dielectric layer 32 are formed of the same material in the above embodiment, different materials may be used, provided that both of the materials are ceramic materials. This is because such ceramic materials can lessen the stress that will be exerted on each other. FIG. 4(c) shows another variation of the table 3. As shown in FIG. 4(c), the electrostatic chuck 32c may have a diameter different from that of the lower electrode 31. FIG. 4(d) shows still another variation of the table 3. As shown in FIG. 4(d), the thickness of the dielectric layer 32 may be arranged not only to have a mode of distribution simply increased toward the central portion but also to provide varied thickness distribution corresponding to desired plasma distribution.

### Second Embodiment

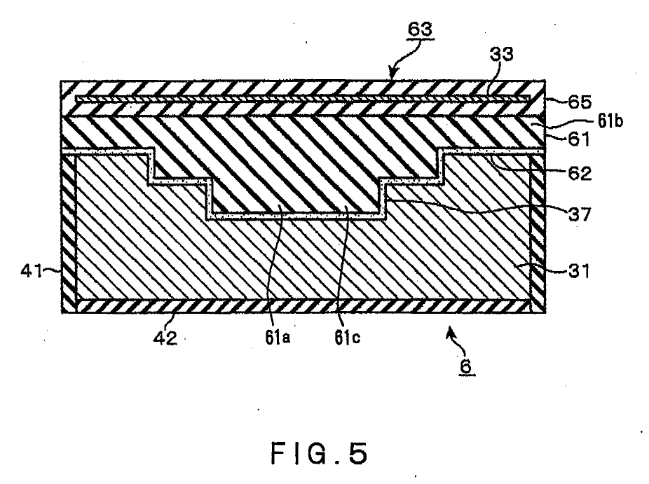

Next, a second embodiment of the table for use in the plasma processing apparatus 2 will be described with reference to FIG. 5. The table 6 shown in FIG. 5 includes the lower electrode 31 similar to that of the table 3 discussed above. In the top face of the lower electrode 31, the recess 37 as described above is provided. On the lower electrode 31, a first circular dielectric layer 61, which corresponds to the insulating material portion described in the above embodiment, is arranged for providing uniformity of the electron distribution density of the plasma over the wafer W. The dielectric layer 61 is fixedly attached onto the lower electrode 31 via an adhesive 62. The dielectric layer 61 includes a projection 61c, which projects downward to cover the whole top face of the lower electrode 31 and is formed such that its thickness becomes gradually greater as one moves from its peripheral portion 61b toward its central portion 61a. In this manner, the dielectric layer 61 is filled in the recess 37.

A top face of the dielectric layer 61 is a flat face, and a circular electrostatic chuck 63 is provided thereon, the chuck 63 having a diameter that is the same as that of the dielectric layer 61. The electrostatic chuck 63 has a structure in which the electrode film 33 is embedded in an insulating material portion 65 corresponding to a second dielectric layer as set forth in claims. The insulating material portion 65 is composed of a dielectric, such as aluminum or the like, and the insulating material portion 65 and the electrode film 33 are formed of the spraying process, as will be described later.

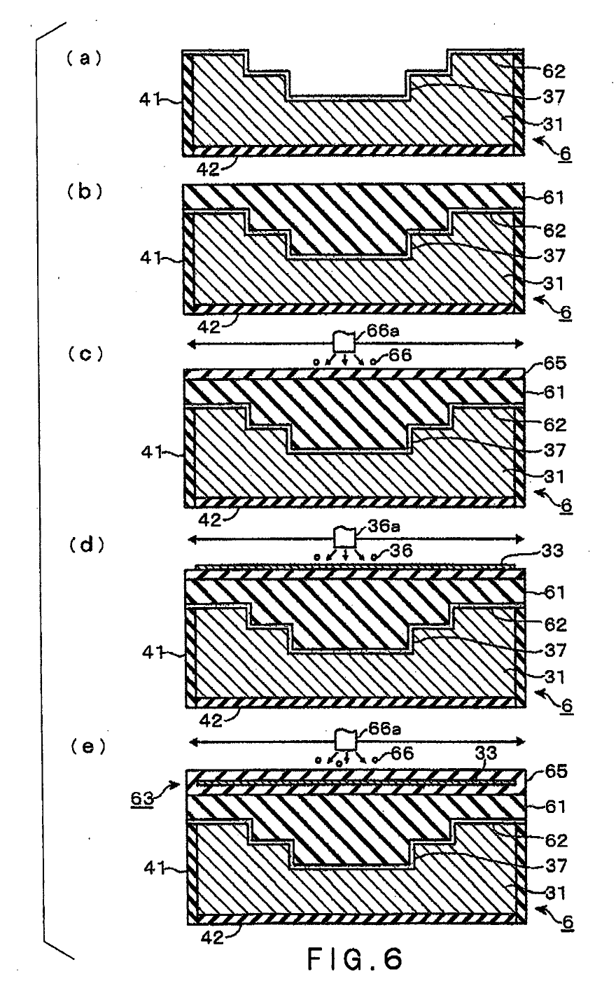

Referring now to FIG. 6, the production process for the table 6 will be described. First, as shown in the drawing, the dielectric layer 61 is attached onto the lower electrode 31 to which the recess 37 and the insulating members 41, 42 are provided, via the adhesive 62 (FIGS. 6(a), 6(b)). Thereafter, a material 66 for constituting the Insulating material portion 65 of the electrostatic chuck is sprayed onto the dielectric layer 61 from a nozzle 66a (FIG. 6(c)), and then the electrode film 33 is formed on the insulating material portion 65 by spraying the electrode film forming material 36 from the nozzle 36a (FIG. 6(d)). Subsequently, the material 66 is sprayed again to cover the electrode film 33 so as to form the electrostatic chuck 63 (FIG. 6(e)). Before attaching the dielectric layer 61 onto the lower electrode 31 or otherwise before spraying the material 66 after attaching the dielectric layer 61 onto the lower electrode 31, for example, surface treatment of the dielectric layer 61 may be performed in order to enhance adhesiveness of the electrostatic chuck 63 formed by, for example, the spraying process, relative to the dielectric layer 61. While the material sprayed on and under the electrode film is preferably ceramic, any other suitable materials may also be used. For Instance, the material sprayed under the electrode film may be a highly adhesive material, while the material sprayed on the electrode film may be a highly magnetically permeable material.

In the table 6 described above, the dielectric layer 61 having the same diameter as that of the electrostatic chuck 63 is provided on the bottom face side of the electrostatic chuck 63. Accordingly, under the electrostatic chuck 63, there is no boundary portion, in which the difference in the coefficient of linear expansion would be seen as in the case of the conventional table, between the dielectric layer and the lower electrode. Instead, the boundary portion, when viewed from the electrostatic chuck 63, exists in an outer circumference of the electrostatic chuck 63 below the dielectric layer 61. Therefore, the stress exerted on the electrostatic chuck 63 can be suppressed even when the temperature change occurs around the table 6 during the plasma process for the wafer W (or use of the table) and/or production of the table 6, thereby avoiding or suppressing damage of the electrostatic chuck 63. According to the configuration of this embodiment, both of the insulating material portion and the electrode film of the electrostatic chuck are formed by the spraying process, as such a higher degree of freedom for controlling the resistance of the material can be obtained and a lower production cost can be achieved.

In this case, the dielectric layer 61 is formed as a sintered body. Therefore, the thickness can be increased as compared with the case of forming it by the spraying process, thereby a higher degree of freedom for production can be provided. Namely, the difference of thickness between the central portion and the peripheral portion can be significantly increased, corresponding to the electron density distribution of the plasma.

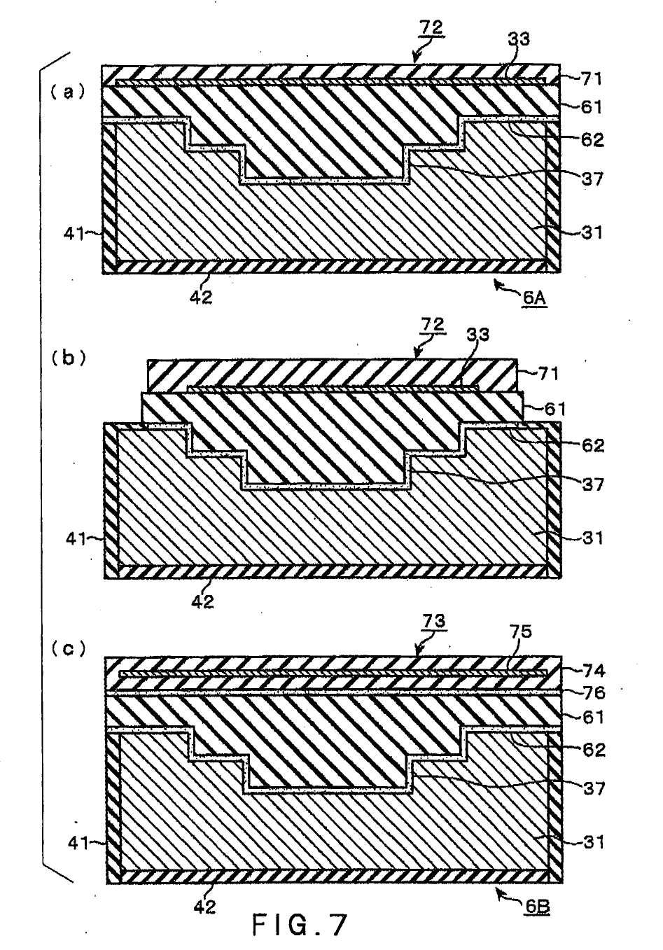

A table 6A shown in FIG. 7(a) is a variation of the table 6 and includes an electrostatic chuck 72 composed of the electrode film 33 and an insulating material portion 71. The insulating material portion 71 consists of only on the top part of the insulating material portion 65 of the electrostatic chuck 63 of the table 6, while it does not have the bottom part of the insulating material portion 65. The table 6A is produced by first attaching the dielectric layer 61 onto the lower electrode 31 in the same manner as in the case of, for example, the table 6, then forming the electrode film 33 on the dielectric layer 61 by the spraying process, and thereafter forming the insulating material portion 71 by spraying the material 66 to cover the electrode film 33. With the configuration of this embodiment, further-lower-cost production can be achieved. FIG. 7(b) shows a variation of the table 6A. As shown in the drawing, the insulating material portion 71 is designed to have a diameter slightly smaller than the top face of the dielectric layer 61. Such configuration is also within the scope of this invention.

A table 6B shown in FIG. 7(c) is another variation of the table 6. The table 6B includes an electrostatic chuck 73 formed in the same manner as the electrostatic chuck 63 previously described, while the insulating material portion 74 and the electrode film 75 constituting together the electrostatic chuck 73 are respectively formed from sintered materials. The electrostatic chuck 73 is fixedly attached onto the dielectric layer 61 via an adhesive 76. In the cases of these tables 6A, 6B, as with the case of the table 6, the dielectric layer 61 extends under each electrostatic chuck 72, 73, and hence there is no boundary portion, as would be seen in the conventional case, between the dielectric layer and the lower electrode. Therefore, damage of each electrostatic chuck 72, 73 due to temperature change can be suppressed.

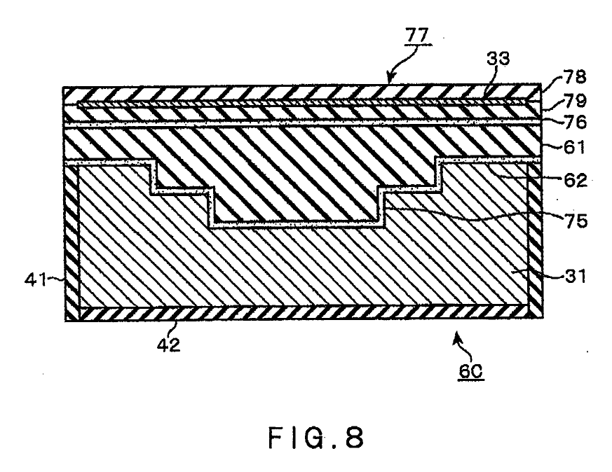

A table 6C shown in FIG. 8 is still another variation of the table 6. While the table 6C is configured in the same manner as the table 6B, it includes an electrostatic chuck 77 formed into a shape similar to the electrostatic chuck 73, in place of employing the electrostatic chuck 73. Namely, the electrostatic chuck 77 includes a top-face-side insulating material portion 78 formed from a dielectric, a bottom-face-side insulating material portion 79 formed from a dielectric, and an electrode film 33 interposed between the top-face-side insulating material portion 78 and the bottom-face-side insulating material portion 79.

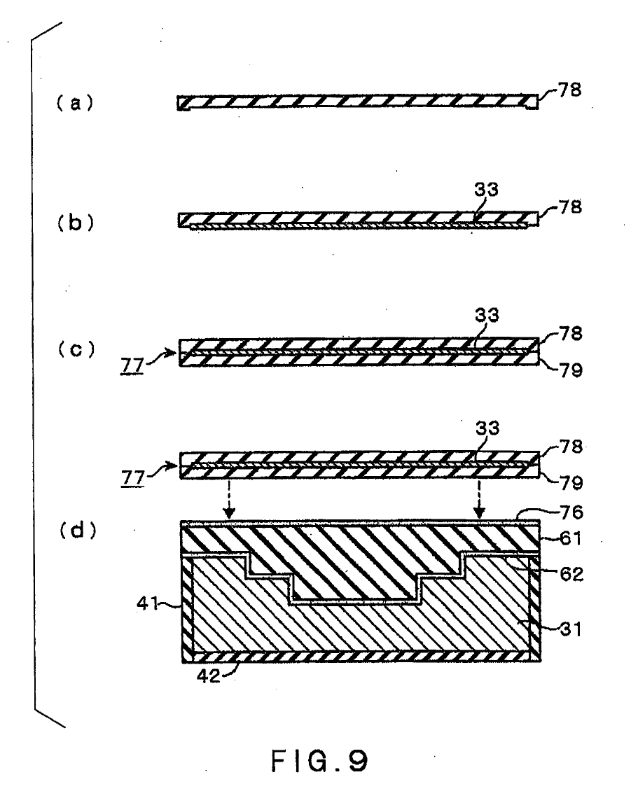

FIG. 9 shows a production process for the table 6C. In this process, for example, the electrode film 33 is first formed by the spraying process on a surface of the top-face-side insulating material 78 that was prepared as a sintered body (FIGS. 8(a), 8(b)). Subsequently, the electrostatic chuck 77 is produced by forming the bottom-face-side insulating material portion 79, by utilizing the spraying process, so as to cover the electrode film 33 (FIG. 8(c)). Thereafter, the electrostatic chuck 77 is attached onto the dielectric layer 61 via the adhesive 76, thus constructing the table 6C.

It should be appreciated that in the second embodiment and the variations thereof, the recess formed in the lower electrode 31 is not limited to have a step-wise shape, like the recess 37, it may be cone-shaped, like the recess 34.

### Third Embodiment

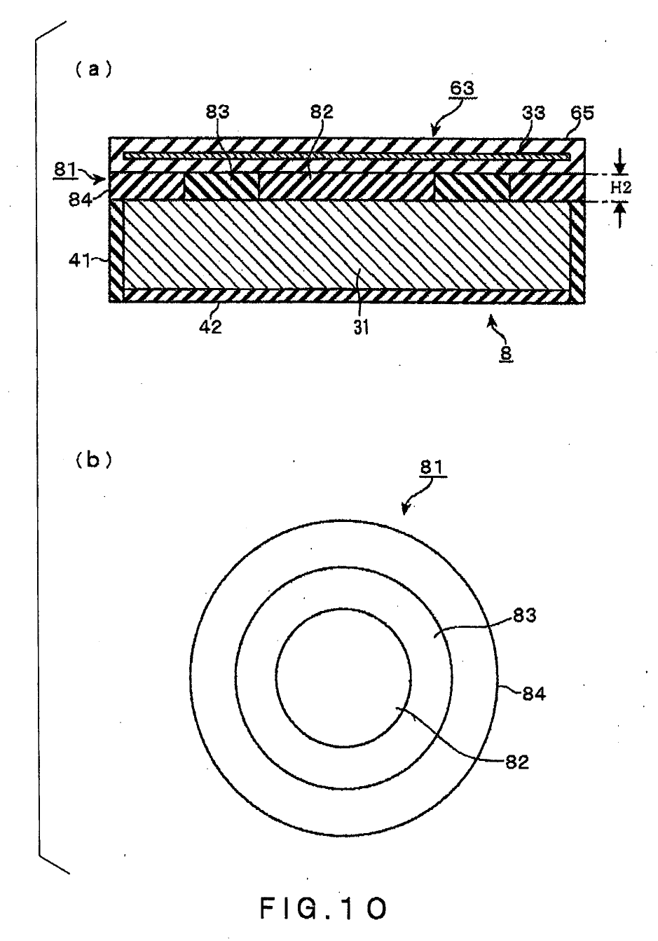

Next, a third embodiment of the table will be described with reference to FIG. 10(a). The table 8 includes the lower electrode 31 and the insulating members 41, 42, in the same manner as the table 3 of the first embodiment. However, the surface of the lower electrode 31 is not provided with the recess, but is formed to have a flat face. In addition, a flat column-like dielectric layer 81 is provided on the lower electrode 31 such that it covers the lower electrode 31. FIG. 10(b) is a view of the dielectric layer 81 when it is viewed from above. As shown in the drawing, the dielectric layer 81 is composed of a circular dielectric member 82 provided in a central portion, and annular dielectric members 83, 84 respectively provided to surround the dielectric member 82. The dielectric members 83, 84 have diameters different from each other, and are arranged concentrically with the center of the dielectric member 82, respectively. These dielectric members 82 to 84 are formed, by the spraying process, from materials different from one another, respectively. The dielectric constants of these dielectric members 82 to 84 are set in a relationship: the dielectric member 82<the dielectric member 83<the dielectric member 84; respectively, in order to provide uniformity of the plasma electron density distribution. That is, the electric constant of each dielectric member is set such that it becomes lower as one moves from the dielectric member provided on the peripheral side toward the dielectric member provided near the center of the lower electrode 31. In other words, the dielectric layer 81, when viewed over the entire body, is configured such that the dielectric constant becomes gradually higher as one moves from its center toward its periphery.

As described in the first embodiment, it is preferred that the thickness of the dielectric layer 81, as shown by H2 in FIG. 10(a), is, for example, 2 mm or less, in order to suppress or avoid damage caused by internal stress during its formation by the spraying process.

In addition, the electrostatic chuck 63, in which each part is formed by the meta-spraying process, as previously described, is layered on the dielectric layer 81 so as to cover the dielectric layer 81.

In such a table 8, each dielectric member 82 to 84 provided below the electrostatic chuck 81 is formed by the spraying process. While, in the conventional table as described above in the column on the background art, the dielectric and the lower electrode are respectively provided as sintered bodies below the electrostatic chuck, the dielectric members 82 to 84 described above are respectively formed by the spraying process. Therefore, even though these dielectric members 82 to 84 have different dielectric constants relative to one another, each dielectric member can be kept in a state closely attached to one another, thereby dispersing the stress, as such preventing separation of the dielectric members from one another. In addition, if each dielectric member 82 to 84 is formed from an inorganic material, such as ceramic or the like, the difference in the coefficient of linear expansion between the respective dielectric members can be controlled to be significantly lower than the difference in the coefficient of linear expansion between the dielectric member and the lower electrode of the conventional case. Accordingly, the stress exerted on the electrostatic chuck 63 of the table 8 due to temperature change during use and/or production of the table 8 can be lessened as compared with the stress exerted on the electrostatic chuck of the conventional table, thereby to suppress damage of the electrostatic chuck 8.

Although, in each table 3, 6 of the first and second embodiments, it is necessary to provide the coolant passage 42 and each recess 34, 37 in the lower electrode 31 such that they do not interfere with wiring and the like provided in the lower electrode 31, there is no need for providing such recess 34 or 37 in the third embodiment, thus facilitating the production. Additionally, because there is no need for providing the dielectric layer 81 to have a portion projecting downward corresponding to each recess 34, 37, the dielectric layer 81 can be formed thinly, as such downsizing the table.

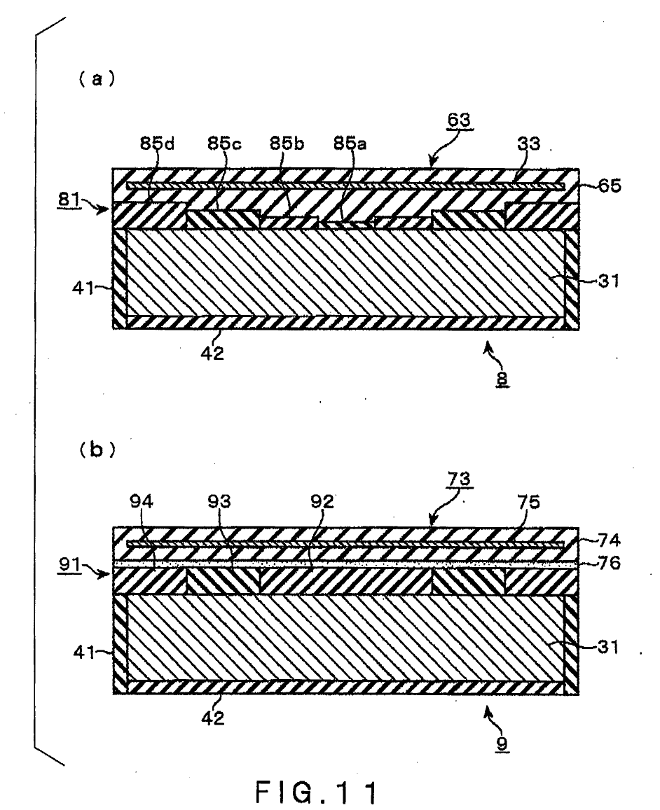

The dielectric layer 81 is configured such that the dielectric constant becomes higher as one moves toward the periphery over the lower electrode 31 while becomes lower as one moves toward the central portion, thereby providing uniformity of the plasma electron density distribution. However, in this case, the number of divided parts of the dielectric layer 81 is not limited to three, but it may be divided into, for example, four parts, i.e., a circular dielectric member 85a, and ring-like dielectric members 85b, 85c, 85d, as shown in FIG. 11(a). Furthermore, these dielectric members 85a to 85d have different thicknesses, respectively.

A table 9 shown in FIG. 11(b) is a variation of the table 8, in which the dielectric layer 91 that is a sintered body is provided on the lower electrode 31 via the adhesive 62, and the electrostatic chuck 73, each part of which is composed of a sintered body, is provided on the dielectric layer 91 via the adhesive 76, as described above. The dielectric layer 91 is composed of dielectric members 92, 93, 94, and these dielectric members 92, 93, 94 are configured in the same manner as the dielectric members 82 to 84, except that they are respectively formed from sintered materials.

In the table 9, since the dielectric members 92 to 94 provided below the electrostatic chuck 73 are all formed from materials of the same kind, i.e., sintered materials. The difference in the coefficient of linear expansion between the dielectric members 92 to 94 is smaller than the difference in the coefficient of linear expansion between the dielectric and the lower electrode below the electrostatic chuck of the conventional table as described in background art. Accordingly, as compared with the electrostatic chuck of the conventional table, the stress received by the electrostatic chuck 73 due to temperature change can be suppressed, as such avoiding or suppressing damage of the electrostatic chuck 73 during plasma formation or production. As is similar to the table 8 described above, enlargement of the thicknesses of the dielectric layer 91 and lower electrode 31 can be controlled, thereby significantly downsizing the table 9.

Also in the table 9, the number of divided parts of the dielectric layer 91 is not limited to three, and the thicknesses of the respective dielectric members constituting the dielectric layer 91 may be different from one another.

The plasma processing apparatus 2 of the embodiment described above is a type of superimposing two kinds of high frequency electric power, one for plasma generation and the other for biasing, and then applying the superimposed electric power to the lower electrode 31. However, although illustration by drawings is omitted, the present invention can also be applied to a type of applying the high frequency electric power for plasma generation to the upper electrode 51, a type of applying the high frequency electric power for plasma generation to the upper electrode 51 as well as applying the high frequency electric power for biasing to the lower electrode 31, respectively, (i.e., upper and lower high frequency application type), or a type of only applying the high frequency electric power for plasma generation to the lower electrode 31. In a broad sense, the present invention can be applied to a plasma processing apparatus having at least one electrode in the processing vessel that can be evacuated. Furthermore, the present invention can also be applied to any other plasma processing apparatuses for use in plasma CVD, plasma oxidation, plasma nitrification, spattering and the like. In addition, the substrate to be processed in this invention is not limited to semiconductor wafers, but substrates, such as LCD substrates, glass substrates, ceramic substrates and the like, can also be used therein.

1. A table for a plasma processing apparatus, used for supporting a substrate to be processed thereon, the table comprising:
an electrically conductive member connected with a high frequency power source and adapted for plasma generation, for drawing ions present in the plasma, or for both of plasma generation and drawing ions;
a dielectric layer provided on a top face of the electrically conductive member, having a central portion and a peripheral portion that are different in thickness relative to each other, and adapted for providing uniformity of high frequency electric field intensity in a plane over the substrate to be processed; and
an electrode film of an electrostatic chuck, provided in the dielectric layer and adapted for electrostatically chucking the substrate onto a top face of the dielectric layer.

2. The table for the plasma processing apparatus according to claim 1, wherein the dielectric layer includes a projection, which projects downward such that its thickness of the central portion is greater than its thickness of the peripheral portion.

3. The table for the plasma processing apparatus according to claim 1, wherein the dielectric layer and the electrode film are formed of sprayed materials, respectively.

4. The table for the plasma processing apparatus according to claim 3, the dielectric layer is configured such that the whole body thereof is formed of the same sprayed material.

5. A table for a plasma processing apparatus, used for supporting a substrate to be processed thereon, the table comprising:
an electrically conductive member connected with a high frequency power source and adapted for plasma generation, for drawing ions present in the plasma, or for both of plasma generation and drawing ions;
a first dielectric layer provided on a top face of the electrically conductive member, having a central portion and a peripheral portion that are different in thickness relative to each other, and adapted for providing uniformity of high frequency electric field intensity in a plane over the substrate to be processed;
a second dielectric layer layered on the first dielectric layer in a range substantially the same as or smaller than a top face of the first dielectric layer; and
an electrode film provided in the second dielectric layer or under the second dielectric layer and adapted for electrostatically chucking the substrate onto the second dielectric layer.

6. The table for the plasma processing apparatus according to claim 5, wherein the first dielectric layer includes a projection, which projects downward such that its thickness of the central portion is greater than its thickness of the peripheral portion.

7. The table for the plasma processing apparatus according to claim 5, wherein the first dielectric layer is formed of a sintered material.

8. The table for the plasma processing apparatus according to claim 5, wherein the second dielectric layer and the electrode film are formed of sprayed materials, respectively.

9. A table for a plasma processing apparatus, used for supporting a substrate to be processed thereon, the table comprising:
an electrically conductive member connected with a high frequency-power source and adapted for plasma generation, for drawing ions present in the plasma, or for both of plasma generation and drawing ions;
a first dielectric layer provided to cover the whole top face of the electrically conductive member, and having a central portion and a peripheral portion that are formed from materials different from each other, such that the dielectric constant of the peripheral portion is higher than the dielectric constant of the central portion in order to provide uniformity of high frequency electric field intensity in a plane over the substrate to be processed;
a second dielectric layer layered on the first dielectric layer; and
an electrode film provided in the second dielectric layer or under the second dielectric layer and adapted for electrostatically chucking the substrate onto the second dielectric layer.

10. The table for the plasma processing apparatus according to claim 9, wherein the first dielectric layer is formed of a sprayed material or of a sintered material.

11. The table for the plasma processing apparatus according to claim 9, wherein the first dielectric layer has top and bottom faces including respectively a flat shape.

12. The table for the plasma processing apparatus according to any one of claims 1, 5 and 9, wherein the electrode film is composed of a high resistance material.

13. The table for the plasma processing apparatus according to claim 11, wherein volume resistivity of the electrode film is within a range of from 10⁻¹ Ω·cm to 10⁸Ω·cm.

14. A plasma processing apparatus comprising:
a processing vessel adapted to provide a plasma process to a substrate to be processed;
a processing gas introducing unit for introducing a processing gas into the processing vessel;
a table for the plasma processing apparatus, provided in the processing vessel;
an upper electrode provided above the table such that it faces the table; and
a means configured to evacuate the interior of the processing vessel,
wherein the table includes:
an electrically conductive member connected with a high frequency power source and adapted for plasma generation, for drawing ions present in the plasma, or for both of plasma generation and drawing irons;
a dielectric layer provided on a top face of the electrically conductive member, having a central portion and a peripheral portion that are different in thickness relative to each other, and adapted for providing uniformity of high frequency electric field intensity in a plane over the substrate to be processed; and
an electrode film of an electrostatic chuck, provided in the dielectric layer and adapted for electrostatically chucking the substrate onto a top face of the dielectric layer.

15. A plasma processing apparatus comprising:
a processing vessel adapted to provide a plasma process to a substrate to be processed;
a processing gas introducing unit for introducing a processing gas into the processing vessel;
a table for the plasma processing apparatus, provided in the processing vessel;
an upper electrode provided above the table such that it faces the table; and
a means configured to evacuate the interior of the processing vessel,
wherein the table includes:
an electrically conductive member connected with a high frequency power source and adapted for plasma generation, for drawing ions present in the plasma, or for both of plasma generation and drawing irons;
a first dielectric layer provided on a top face of the electrically conductive member, having a central portion and a peripheral portion that are different in thickness relative to each other, and adapted for providing uniformity of high frequency electric field intensity in a plane over the substrate to be processed;
a second dielectric layer layered on the first dielectric layer in a range substantially the same as or smaller than a top face of the first dielectric layer; and
an electrode film provided in the second dielectric layer or under the second dielectric layer and adapted for electrostatically chucking the substrate onto the second dielectric layer.

16. A plasma processing apparatus comprising:
a processing vessel adapted to provide a plasma process to a substrate to be processed;
a processing gas introducing unit for introducing a processing gas into the processing vessel;
a table for the plasma processing apparatus, provided in the processing vessel;
an upper electrode provided above the table such that it faces the table; and
a means configured to evacuate the interior of the processing vessel,
wherein the table includes:
an electrically conductive member connected with a high frequency power source and adapted for plasma generation, for drawing ions present in the plasma, or for both of plasma generation and drawing irons;
a first dielectric layer provided to cover the whole top face of the electrically conductive member, and having a central portion and a peripheral portion that are formed from materials different from each other, such that the dielectric constant of the peripheral portion is higher than the dielectric constant of the central portion in order to provide uniformity of high frequency electric field intensity in a plane over the substrate to be processed;
a second dielectric layer layered on the first dielectric layer; and
an electrode film provided in the second dielectric layer or under the second dielectric layer and adapted for electrostatically chucking the substrate onto the second dielectric layer.
